(19) United States
(12) Patent Application Publication
(10) Pub. No.: US 2008/0237689 A1
(43) Pub. Date: Oct. 2, 2008

(54) NONVOLATILE SEMICONDUCTOR MEMORY DEVICE, METHOD FOR MANUFACTURING THE SAME, AND SEMICONDUCTOR DEVICE

(75) Inventor: Yoji Kitano, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/054,980

(22) Filed: Mar. 25, 2008

(30) Foreign Application Priority Data
Mar. 29, 2007 (JP) 2007-088238

(51) Int. Cl. H01L 29/788; H01L 21/336

(52) U.S. Cl. 257/316; 438/257; 257/E29.3; 257/E21.422

(57) ABSTRACT

A nonvolatile semiconductor memory device includes a first insulating film formed on a semiconductor substrate, a floating gate formed on the first insulating film, a second insulating film on the floating gate, a semiconductor layer formed on the second insulating film, a gate insulating film formed on the semiconductor layer, and a control gate formed on the gate insulating film. The semiconductor substrate is provided with a first source and a first drain both for writing of data, and the semiconductor layer below both sides of the control gate is provided with a second source and a second drain both for readout of the data.

The entire disclosure of Japanese Patent Application No. 2007-088238, filed Mar. 29, 2007 is expressly incorporated by reference herein.

### BACKGROUND OF THE INVENTION

1. Technical Field

The present invention relates to a nonvolatile semiconductor memory device, a method for manufacturing the same, and a semiconductor device.

2. Related Art

JP-A-5-282884 and JP-A-8-816344 are examples of related art, disclosing known nonvolatile semiconductor memory devices with a structure called a stacked gate type, in which a control gate is provided on a channel region with a floating gate intervened therebetween to implement electrical writing and erasing. With this type of nonvolatile semiconductor memory device, to write data, a high voltage is applied to the control gate and electrons are injected from a side of a substrate into the floating gate through the use of hot electrons or tunneling effect. To erase data, the high voltage is applied to the side of the substrate and electric charges stored in the floating gate are pulled out to the side of the substrate through the use of the tunneling effect.

Another example of related art is T. Sakai et al. “Separation by bonding Si Islands (SBSI) for LSI Application”, Second International SiGe Technology and Device Meeting, Meeting Abstract, pp. 230-231, May (2004). This example discloses a method for forming an SOI (Silicon On Insulator) transistor at low cost by forming an SOI layer on a bulk substrate. By this method disclosed in the above example, only a Si/SiGe layer, which is formed on a Si substrate, is selectively removed using a difference in selectivity between the Si and the SiGe to thereby form a hollow portion between the Si substrate and the Si layer. Subsequently, a SiO₂ layer is filled between the Si substrate and the Si layer by performing thermal oxidation of the Si that is exposed inside the hollow portion, thereby forming a BOX layer between the Si substrate and the Si layer.

A problem with the known nonvolatile semiconductor memory devices lies in the difficulty of reducing a distance between a control gate electrode and a channel region since a floating gate surrounded by an insulating layer is formed on the channel region. Thus, it is difficult with the nonvolatile semiconductor memory device to set a threshold value low, leading to the difficulty of speeding up a readout operation. It is also difficult to reduce a voltage required for the readout operation, that is, a driving voltage.

### SUMMARY

An advantage of the present invention is to provide a nonvolatile semiconductor memory device that achieves speeding up of a readout operation, a method for manufacturing the same, and a semiconductor device. Another advantage of the present invention is to provide a nonvolatile semiconductor memory device that achieves reduction in a driving voltage, a method for manufacturing the same, and a semiconductor.

According to a first aspect of the invention, a nonvolatile semiconductor memory device includes a first insulating film formed on a semiconductor substrate, a floating gate formed on the first insulating film, a second insulating film on the floating gate, a semiconductor layer formed on the second insulating film, a gate insulating film formed on the semiconductor layer, and a control gate formed on the gate insulating film. The semiconductor substrate is provided with a first source and a first drain both for writing of data, and the semiconductor layer below both sides of the control gate is provided with a second source and a second drain both for readout of the data.

Herein, “writing of data” means an operation of storing electric charges in the floating gate. For example, data is written by generating hot electrons near the first drain and then injecting them into the floating gate. Furthermore, “readout of data” means an operation of detecting a storage level of electric charges in the floating gate. In the case where the storage level of the electric charges in the floating gate is changed, a threshold value of the semiconductor layer between the second source and the second drain positioned on the floating gate, that is, a threshold value of a channel region, is changed. Therefore, data is read out by detecting the change of the threshold value according to the amount of a current flowing between the second source and the second drain or an ON or OFF state of the channel region.

The first source and drain exhibit breakdown voltage as high as 15 to 20 [V] and the second source and drain exhibit lower breakdown voltage.

According to the first aspect of the invention, the nonvolatile semiconductor memory device does not have the floating gate between the control gate and the channel region sandwiched between the second source and drain, thereby achieving reduction in a distance between the channel region and the control gate. Thus, the threshold value at the time of readout of data can be reduced to thereby speed up the readout operation as well as to reduce a driving voltage.

According to a second aspect of the invention, a method for manufacturing a nonvolatile semiconductor memory device includes forming a first semiconductor layer on a semiconductor substrate, forming a second semiconductor layer to be served as a floating gate on the first semiconductor layer, forming a third semiconductor layer on the second semiconductor layer, forming a fourth semiconductor layer on the third semiconductor layer, forming a first groove to expose a side surface of each of the fourth, the third, the second, and the first semiconductor layers by partially etching these semiconductor layers in sequence, forming a first hollow portion between the semiconductor substrate and the second semiconductor layer and a second hollow portion between the second semiconductor layer and the fourth semiconductor layer by etching the first and the third semiconductor layers with the first groove intervened, under an etching condition that the first and the third semiconductor layers are more easily etched than the second and the fourth semiconductor layers, forming a first insulating film inside the first hollow portion and a second insulating film inside the second hollow portion, forming a gate insulating film on the fourth semiconductor layer, forming a control gate on the gate insulating film, forming a first source and a first drain both for wiring of data on the semiconductor substrate, and forming a second source and a second drain both for readout of the data on the fourth semiconductor layer below opposite sides of the control gate.

Here, “the first semiconductor layer” and “the second semiconductor layer” are exemplified as a single-crystal silicon germanium layer referred to as a SiGe layer. Furthermore, “the second semiconductor layer” and “the fourth semiconductor layer” are exemplified as a single-crystal Si layer.

It is preferable that the method for manufacturing a nonvolatile semiconductor memory device further include forming a second groove penetrating each of the fourth, the third, the second, and the first semiconductor layers by partially etching these semiconductor layers in sequence before formation of the first and the second hollow portions, and forming a supporter for supporting the second and the fourth semiconductor layers at least inside the second groove before the formation of the first and the second hollow portions.

By the method for manufacturing a nonvolatile semiconductor memory device according to the second aspect of the invention, the nonvolatile semiconductor memory device according to the first aspect of the invention can be manufactured by a so-called SBSI method. Therefore, such a nonvolatile semiconductor memory device can be provided that achieves reduction in the threshold value at the time of readout of data to thereby speed up the readout operation as well as to reduce a driving voltage.

According to a third aspect of the invention, a semiconductor device includes the nonvolatile semiconductor memory device according to the first aspect of the invention, an SOI transistor formed with the nonvolatile semiconductor memory device on the same semiconductor substrate, and a bulk transistor formed directly to the semiconductor substrate.

Here, “the SOI transistor” means a transistor formed on the semiconductor layer such as the second semiconductor layer or the fourth semiconductor layer on the insulating film.

With this structure, the nonvolatile semiconductor memory device is incorporated, thereby realizing a high speed LSI (Large Scale Integration) with low power consumption.

### BRIEF DESCRIPTION OF THE DRAWINGS

The invention will be described with reference to the accompanying drawings, wherein like numbers reference like elements.

FIG. 1 is a view showing a configuration example of a nonvolatile memory 100 according to a first embodiment.

FIG. 2A is a view showing a configuration example of a nonvolatile memory 200 according to a second embodiment.

FIG. 2B is a cross-sectional view of the nonvolatile memory 200 in FIG. 2A along the line x-x′.

FIG. 2C is a cross-sectional view of the nonvolatile memory 200 in FIG. 2A along the line y-y′.

FIGS. 3A and 3B are each a first view showing a method for manufacturing the nonvolatile memory 200.

FIGS. 4A and 4B are each a second view showing the method for manufacturing the nonvolatile memory 200.

FIGS. 5A and 5B are each a third view showing the method for manufacturing the nonvolatile memory 200.

FIGS. 6A and 6B are each a fourth view showing the method for manufacturing the nonvolatile memory 200.

FIGS. 7A and 7B are each a fifth view showing the method for manufacturing the nonvolatile memory 200.

FIGS. 8A and 8B are each a sixth view showing the method for manufacturing the nonvolatile memory 200.

FIGS. 9A and 9B are each a seventh view showing the method for manufacturing the nonvolatile memory 200.

FIGS. 10A and 10B are each an eighth view showing the method for manufacturing the nonvolatile memory 200.

FIGS. 11A and 11B are each a ninth view showing the method for manufacturing the nonvolatile memory 200.

FIGS. 12A and 12B are each a tenth view showing the method for manufacturing the nonvolatile memory 200.

FIGS. 13A and 13B are each an eleventh view showing the method for manufacturing the nonvolatile memory 200.

FIGS. 14A and 14B are each a twelfth view showing the method for manufacturing the nonvolatile memory 200.

### DESCRIPTION OF EXEMPLARY EMBODIMENTS

Embodiments according to the present invention will be described hereinafter with reference to drawings.

### First Embodiment

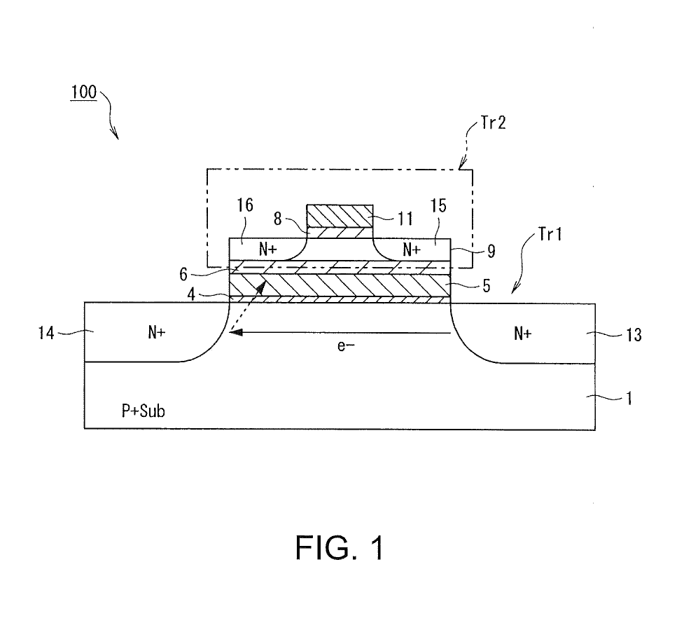

FIG. 1 is a view showing an example of a cross-sectional configuration of a nonvolatile memory 100 according to a first embodiment of the invention.

In this nonvolatile memory 100 shown in FIG. 1, a floating gate 5 is formed on a Si substrate 1 with a SiO₂ film 4 intervened therebetween. A Si layer, that is, an SOI layer, 9 is formed on the floating gate 5 with a SiO₂ film 6 intervened therebetween. The floating gate 5, which is defined as, for example, a Si layer doped with an N-type impurity such as phosphorus, is electrically insulated from a surrounding conductive layer or the like by the SiO₂ films 6, 4, covering front and rear surfaces or by an insulating film, not shown, covering a side surface. A control gate 11 is formed on the SOI layer 9 with a gate oxide film 8 intervened therebetween.

A source layer 13 of high breakdown voltage and a drain layer 14 of high breakdown voltage are formed on the Si substrate 1 below opposite sides of the floating gate 5, respectively. The source layer 13 and the drain layer 14, which are defined as, for example, an N-type impurity diffused layer (N+), exhibit the breakdown voltage of about 15 to 20 [V], for example. A source layer 15 of low breakdown voltage and a drain layer 16 of low breakdown voltage are formed on the SOI layer 9 below opposite sides of the control gate 11. The source layer 15 and the drain layer 16, which are defined as, for example, an N-type impurity diffused layer (N+), exhibit breakdown voltage of about 3 to 5 [V], for example.

In this nonvolatile memory 100, a transistor Tr1 of high breakdown voltage, specifically for writing and erasing of data is composed of the source layer 13 and the drain layer 14 both formed on the Si substrate 1, the control gate 11, and the like. A transistor Tr2 with low breakdown voltage, specifically for readout of data is composed of the source layer 15 and the drain layer 16 both formed on the SOI layer 9, the control gate 11, and the like. This transistor Tr2 of low breakdown voltage is defined as, for example, an SOI transistor of a complete depletion type.

Next, the nonvolatile memory 100 shown in FIG. 10 will be described with respect to a writing method, an erasing method, and a read-in method of data such as a program.

In the nonvolatile memory 100, data is written in the floating gate 5 using a channel hot electron (CHE) current generated in the transistor Tr1 of high breakdown voltage. Specifically, a voltage of 5 to 10 [V] is applied to each of the control gate 11 and the drain layer 14 while a voltage of 0 [V] is applied to the source layer 13 to thereby generate a high electric field between the source layer 13 and the drain layer 14. By setting the voltage as described above, in the transistor Tr1 of high breakdown voltage, electrons flows from the source layer 13 to the drain layer 14 while undergoing acceleration by the high electric field. The hot electrons are pulled out by the electric potential of the control gate to cross over a barrier such as an oxide film/silicone, thereby being injected into the floating gate 5. Data is written in this manner.

As described above, the floating gate 5 is electrically floating since a periphery thereof is covered with the SiO₂ films 4, 6, or the like, so that the injected electric charges are held inside the floating gate 5 until the next pull-out operation, that is, the next data erasing operation. Furthermore, to erase data, a voltage of 15 to 20 [V] is applied to each of the source layer 13 and the drain layer 14 while a voltage of 0 [V] is applied to the control gate 11. By setting the voltage as described above, the electrons stored in the floating gate 5 flow as an F—N tunneling current to the side of the Si substrate 1 to thereby erase data.

Data is read in by detecting change in a threshold value of the transistor Tr2 with low breakdown voltage. Specifically, since a channel region of the transistor Tr2 with low breakdown voltage is disposed directly above the floating gate 5, a back-gate bias is applied to the channel region to thereby change the threshold value of the transistor Tr2 with low breakdown voltage in the case where the electric charges are stored in the floating gate 5.

In the case of a large number of electrons stored in the floating gate 5, which indicates that the data is written in, a negative back-gate bias is applied to the channel region of the transistor Tr2 with low breakdown voltage, so that the threshold is reduced. In the case of a small number of electrons stored in the floating gate 5, which indicates that the data is not written in, the back-gate bias is hardly applied to the channel region of the transistor Tr2 with low breakdown voltage, so that the threshold is comparatively high compared with the case where data is written in.

Therefore, on the condition that a voltage of 2 to 5 [V] is applied to each of the control gate 11 and the drain layer 16 while a voltage of 0 [V] is applied to the source layer 15, the channel region is turned into an ON state and a current flows between the source layer 15 and the drain layer 16 in the case where data is written in. On the other hand, the channel region is turned into an OFF state and the current does not flow between the source layer 15 and the drain layer 16 in the case where data is not written in. As described above, data can be read out by detection as to whether or not the current flows between the source layer 15 and the drain layer 16, in other words, detection as to an ON/OFF state of the channel region. One of logical values, [0], [1] is set to the case where the channel region of the transistor Tr2 with low breakdown voltage is turned into the ON state while the other one of logical values, [0], [1] is set to the case where the channel region is turned in the OFF state, respectively. In this manner, the binarized data can be read out.

According to the first embodiment of the invention described above, the floating gate 5 is not placed between the channel region of the transistor Tr2 with low breakdown voltage and the control gate 11 but is placed at a side under the channel region, so that a distance between the channel region and the control gate can be reduced. Therefore, the threshold value at the time of data readout operation can be reduced to thereby speed up the readout operation as well as to reduce a driving voltage.

In the above first embodiment, the Si substrate 1 corresponds to “a semiconductor substrate” of the invention and the SiO₂ film 4 corresponds to “a first insulating film” of the invention. The SiO₂ film 6 corresponds to “a second insulating film” of the invention, the Si layer 9 corresponds to “a semiconductor layer” of the invention, and the gate oxide film 8 corresponds to “a gate insulating film” of the invention. The source layer 13 and the drain layer 14 correspond to “a first source” and “a first drain”, respectively, and the source layer 15 and the drain layer 16 correspond to “a second source” and “a second drain”, respectively. The nonvolatile memory 100 corresponds to “a nonvolatile semiconductor memory device” of the invention.

### Second Embodiment

A configuration example of a nonvolatile memory 200 according to a second embodiment of the invention will be described next.

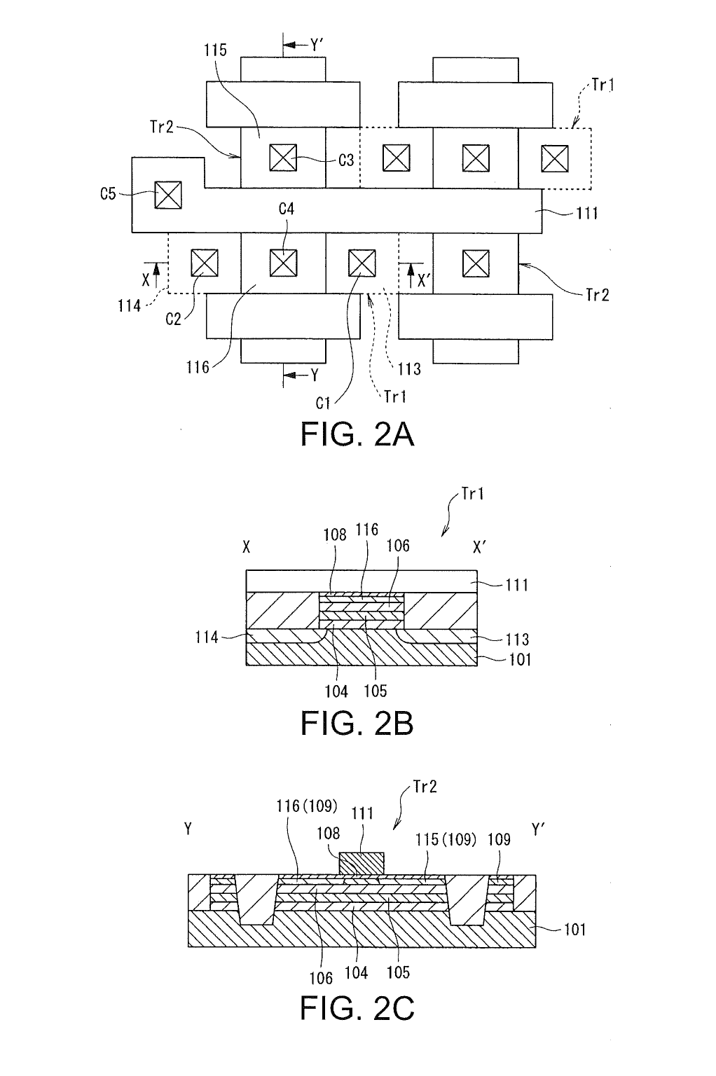

FIGS. 2A to 2C are each a view showing the configuration example of the nonvolatile memory 200. FIG. 2A is a plane view of the nonvolatile memory 200. FIG. 2B is a cross-sectional view of the nonvolatile memory 200 in FIG. 2A along the line x-x′. FIG. 2C is a cross-sectional view of the nonvolatile memory 200 in FIG. 2A along the line y-y′. It is to be noted that illustration of an interlayer insulating film is omitted from FIGS. 2A to 2C to prevent drawing from being complicated.

In this nonvolatile memory 200 as shown in FIGS. 2A to 2C, in a manner similar to the nonvolatile memory 100 described in the first embodiment, a floating gate 105 is formed on a Si substrate 101 with a SiO₂ film 104 intervened therebetween. An Si layer, that is, an SOI layer, 109 is formed on the floating gate 105 with a SiO₂ film 106 intervened therebetween. The floating gate 105, which is defined as, for example, a Si layer doped with an N-type impurity such as phosphorus, is electrically insulated from a surrounding conductive layer or like by the SiO₂ films 106, 104, covering front and rear surfaces or by an insulating film, not shown, covering a side surface. A control gate 111 is formed on the SOI layer 109 with a gate oxide film 108 intervened therebetween.

A source layer 113 of high breakdown voltage and a drain layer 114 of high breakdown voltage are formed on the Si substrate 101 below opposite sides of the floating gate 105, respectively. The source layer 113 and the drain layer 114, which are defined as, for example, an N-type impurity diffused layer (N+), exhibit breakdown voltage of about 15 to 20 [V]. A source layer 115 of low breakdown voltage and a drain layer 116 of low breakdown voltage are formed on the SOI layer 109 below opposite sides of the control gate 111. The source layer 115 and the drain layer 116, which are defined as, for example, an N-type impurity diffused layer (N+), exhibit the breakdown voltage of about 3 to 5 [V].

In this nonvolatile memory 200, the transistor Tr1 of high breakdown voltage, specifically for writing and erasing of data is composed of the source layer 113 and the drain layer 114 both formed on the Si substrate 1, the control gate 11, and the like. A transistor Tr2 with low breakdown voltage, specifically for readout of data is composed of the source layer 115 and the drain layer 116 both formed on the SO layer 109, the control gate 11, and the like.

The nonvolatile memory 200 is different from the aforementioned nonvolatile memory 100 in that the source and the drain of the transistor Tr1 with high breakdown voltage, and the source and the drain of the transistor Tr2 with low breakdown voltage are not oriented in the same direction but oriented in an X-direction and a Y-direction, respectively, in a plane view. Specifically, the direction of the source and the drain of the transistor Tr1 with high breakdown voltage is perpendicular to the direction of the source and the drain of the transistor Tr2 with low breakdown voltage in a plane view.

With the structure described above, the nonvolatile memory 200 can be manufactured by an SBSI method. The floating gate 105 is formed directly above the channel region including an end of the drain of the transistor Tr1 of high breakdown voltage, with the SiO₂ film 104 intervened between the floating gate 105 and the channel region, so that the hot electrons generated around the end of the drain can be injected into the floating gate 105. Thus, by setting the voltage in a manner similar to the case of the nonvolatile memory 100, data can be written in, erased from, and read in with the floating gate 105.

Next, a method for manufacturing the nonvolatile memory 200 will be described.

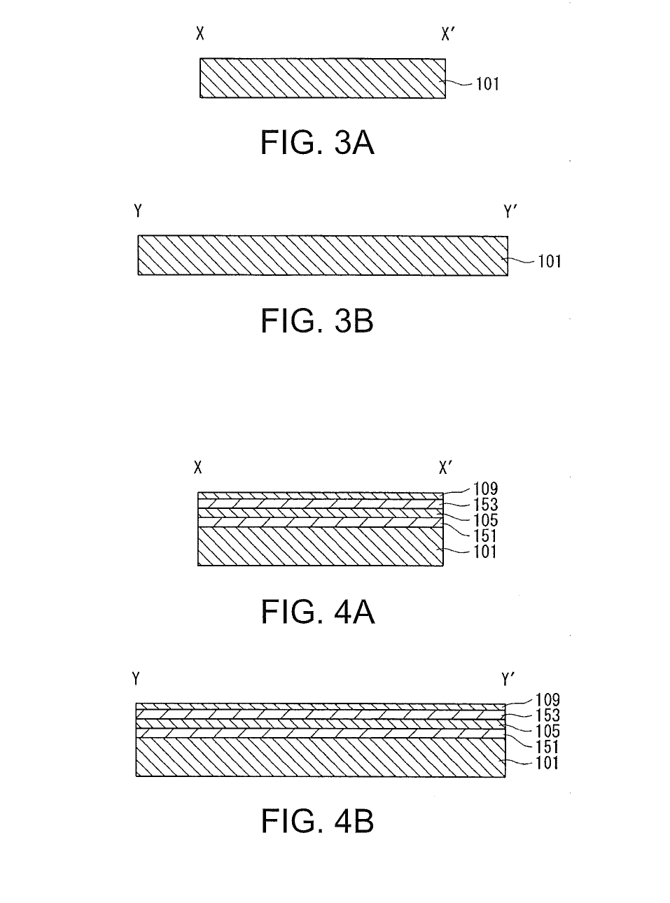

FIGS. 3A to 14B are each a process drawing illustrating a method for manufacturing the nonvolatile memory 200 according to the second embodiment of the invention. FIGS. 3A, 4A, 5A, 6A, 7A, 8A, 9A, 10A, 11A, 12A, 13A, and 14A are each a cross-sectional view of the nonvolatile memory 200 in FIG. 2A along the line x-x′. FIGS. 3B, 4B, 5B, 6B, 7B, 8B, 9B, 10B, 11B, 12B, 13B, and 14B are each a cross-sectional view of the nonvolatile memory 200 in FIG. 2A along the line y-y′. Described herein is the case where the nonvolatile memory 200 shown in FIGS. 2A to 2C is manufactured by the SBSI method.

First, as shown in FIGS. 3A and 3B, the bulk Si substrate 101 is prepared. Next, as shown in FIGS. 4A and 4B, a SiGe layer 151, a Si layer 105, a SiGe layer 153, and a Si layer 109, all of which are single crystals, are laminated in sequence on the Si substrate 101. Herein, the Si layer 105 is a layer to be set to a floating gate and the Si layer 109 is set to the SOI layer to be provided with the transistor Tr2 of low breakdown voltage. The SiGe layer 151, the Si layer 105, the SiGe layer 153, and the Si layer 109 are formed in succession by an epitaxial growth method, for example.

Herein, before formation of the SiGe layer 151, a silicon buffer (Si-buffer) layer in a single crystal structure, not shown, may be thinly formed on the Si substrate 101, and the SiGe layer 151 may be formed on the Si-buffer layer. A film quality of the semiconductor film formed by the epitaxial growth method is highly affected by a crystal condition of a receiving surface as a base. Therefore, improvement in a film quality of the SiGe layer 151, for example, reduction in a crystal fault, can be achieved by forming the SiGe layer 151 not directly on the Si substrate 101 but on the Si-buffer layer with a less crystal fault compared with that of a front surface of the Si substrate 101.

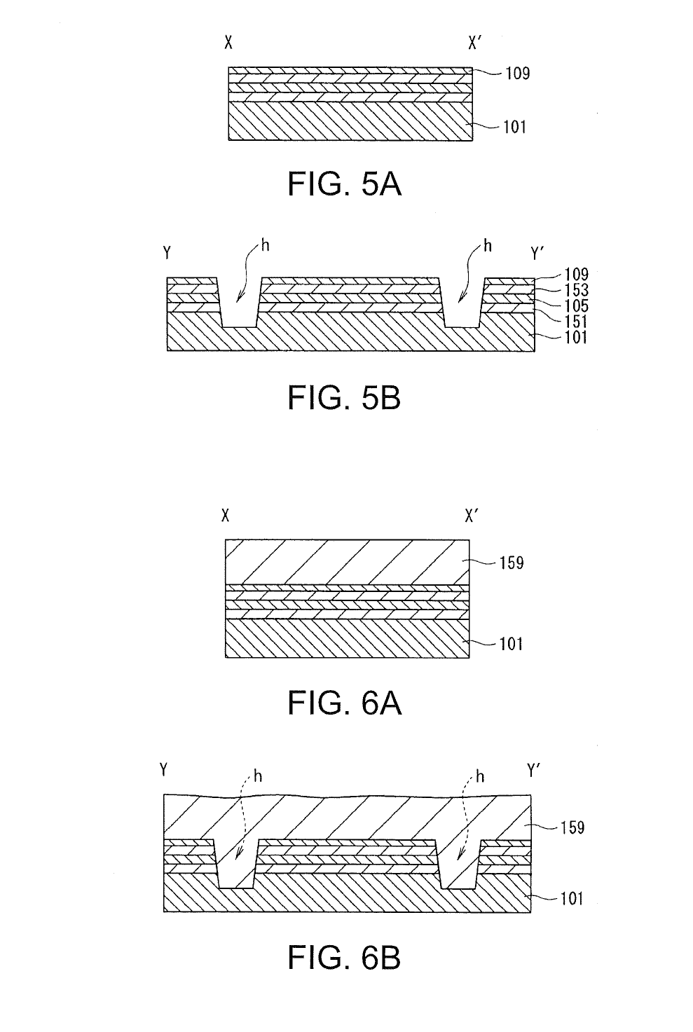

Next, as shown in FIGS. 5A and 5B, the Si layer 109, the SiGe layer 153, the Si layer 105, and the SiGe layer 151 are partially subjected to etching in sequence by photolithography and etching techniques. Thus, supporting via holes h are formed in the region overlapped with an element isolation region in a plane view. Each of the supporting via holes penetrates the Si layer 109, the SiGe layer 153, the Si layer 105, and the SiGe layer 151 and has a bottom surface set to the Si substrate 101. In the etching process for forming the supporting via holes h, the etching may be stopped when reaching the front surface of the Si substrate 101, or the Si substrate 101 may be overetched to form concave parts as shown in FIG. 5B.

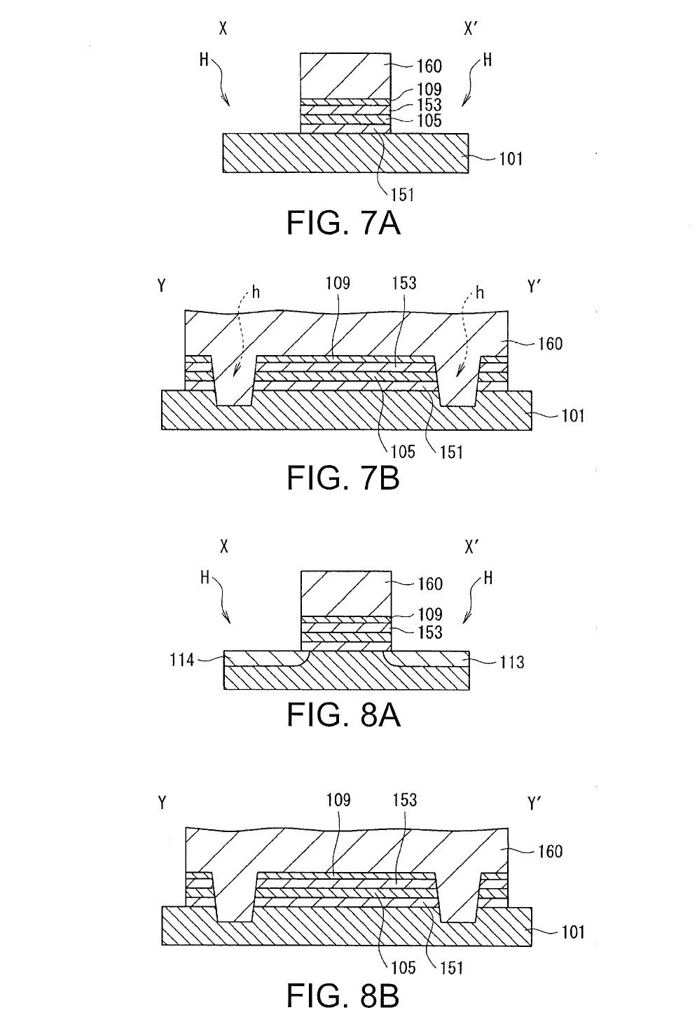

Next, as shown in FIGS. 6A and 6B, a supporting film 159 is formed over an entire surface on the Si substrate 101 in a manner to fill up the supporting holes h. The supporting film 159, which is defined as, for example, a silicone oxide (SiO₂) film, is formed by a CVD method, for example. Subsequently, as shown in FIGS. 7A and 7B, the supporting film 159, the Si layer 109, the SiGe layer 153, the Si layer 105, and the SiGe layer 151 are partially subjected to etching in sequence by the photolithography and etching techniques to thereby form a supporter 160 from the supporting film 159 as well as to thereby form grooves H in a manner to expose a front surface of the Si substrate 101 and each of side surfaces of the Si layer 109, the SiGe layer 153, the Si layer 105, and the SiGe layer 151. In the etching process for forming the grooves H, the etching may be stopped when reaching the front surface of the Si substrate 101 as shown in FIG. 7B, or the Si substrate 101 may be overetched to form concave parts.

Next, the N-type impurity such as phosphorus or arsenic is ion-implanted into the front surface of the Si substrate 101, which is exposed under the supporter 160. The Si substrate 101 is then subjected to a thermal treatment, which is also referred to as “a first anneal” hereinafter, in order to activate the aforementioned N-type impurity. In this manner, as shown in FIG. 8A, the source layer 113 of high breakdown voltage and the drain layer 114 of high breakdown voltage are formed on the Si substrate 101 exposed under the supporter 160. The thermal treatment, i.e., the first anneal described above may double as a second anneal described later. Specifically, in the process shown in FIGS. 8A and 8B, only the ion impletion of the N-type impurity, not the first anneal, is implemented. After completion of the ion implantation of the N-type impurity into the Si layer 109, as shown in FIGS. 14A and 14B, the first anneal and the second anneal may be implemented simultaneously to thereby form the source layer 113 of high breakdown voltage and the drain layer 114 of high breakdown voltage.

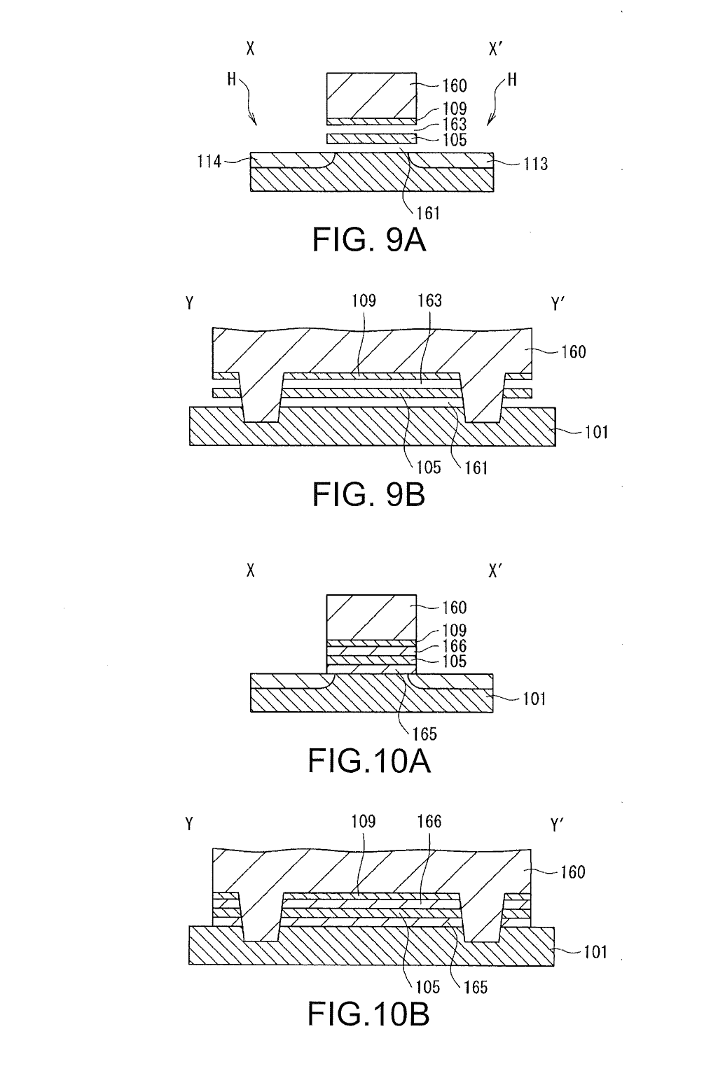

Next, in FIGS. 8A and 8B, HF—HNO3 solution is brought in contact with each of the side surfaces of the Si layer 109, the SiGe layer 153, the Si layer 105, and the SiGe layer 151, with the grooves H intervened. In this manner, the SiGe layers 151, 153 are selectively etched and removed. Thus, as shown in FIGS. 9A and 9B, a first hollow portion 161 is formed between the Si substrate 101 and the Si layer 105 while a second hollow portion 163 is formed between the Si layer 105 and the Si layer 109. Only the SiGe layers are etched and removed while leaving the Si layers 105, 109 by the wet etching using the HF—HNO3 solution since the etching rate of the SiGe is greater than that of the Si, which means the large etching selectivity of the SiGe against the Si. After formation of the hollow portions 161, 163, the front surface and the side surface of the Si layer 109 are supported by the supporter 160 while the side surface of the Si layer 105 is supported by the supporter 160.

Next, the Si substrate 101 is arranged inside an oxidation atmosphere such as oxygen (O₂) and is subjected to the thermal treatment in this condition. In this manner, front and rear surfaces of the Si layer 105, a rear surface of the Si layer 109, and the front surface of the Si substrate 101, which are exposed to either of the first or second hollow portions 161, 163, are thermally oxidized to thereby form SiO₂ films 165, 166, as shown in FIGS. 10A and 10B. Insides of the first and second hollow portions are completely filled upon formation of those SiO₂ films 165, 166.

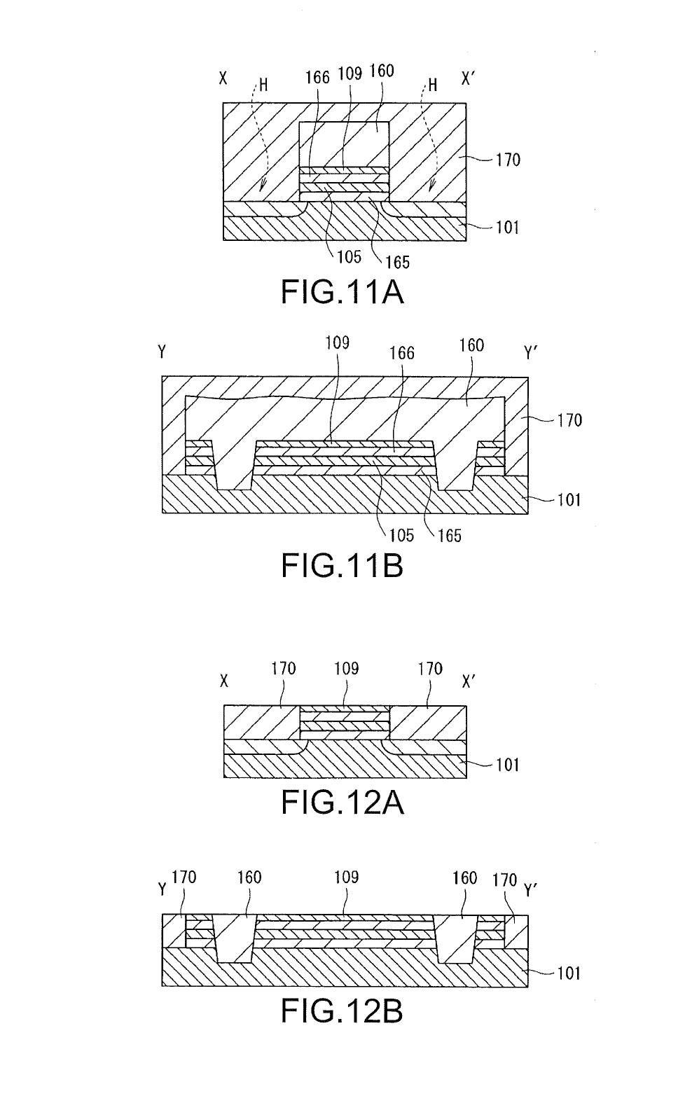

Subsequently, as shown in FIGS. 11A to 11C, the grooves H are filled upon formation of an insulating film 170 over an entire part above the Si substrate 101 by the CVD method or the like. This insulating film 170 is defined as, for example, the SiO₂ film. The insulating film 170 covering the entire part above the Si substrate 101 and the supporter 160 placed below the insulating film 170 are flattened by a CMP method and then etched with a DHF solution. In this manner, the front surface of the Si layer 109 is exposed as shown in FIGS. 12A and 12B.

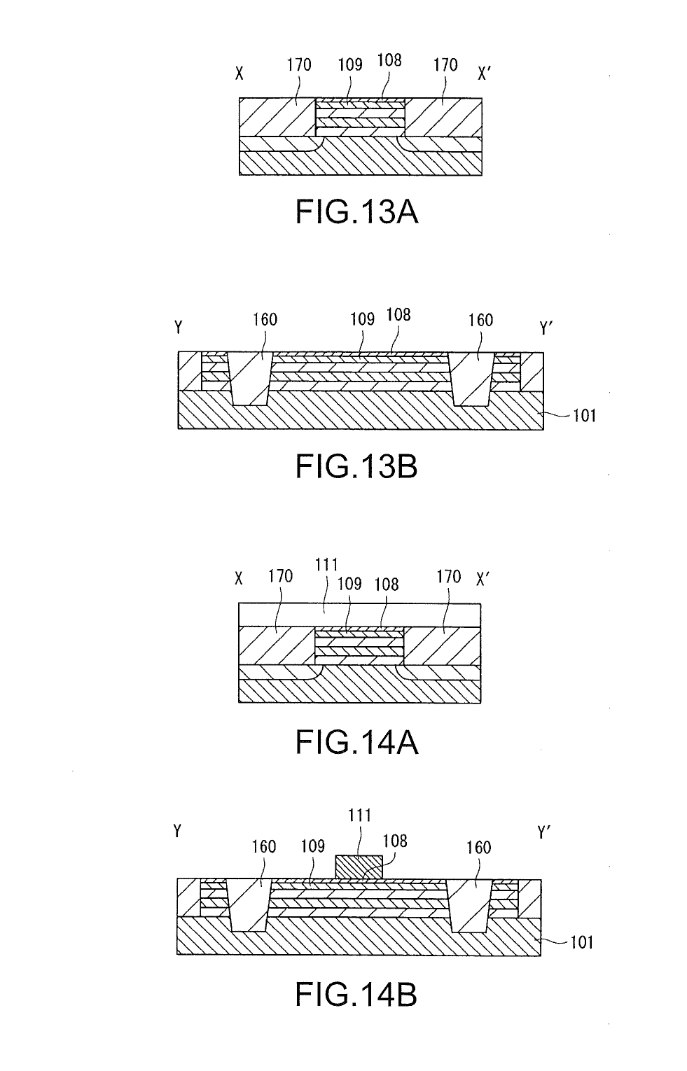

Next, as shown in FIGS. 13A and 13B, the front surface of the Si layer 109 is thermally oxidized to thereby form a gate oxidation film 108. Thereafter, a polysilicon layer is formed on the Si layer 109 provided with the gate oxidation film 108, by the CVD method or the like. Furthermore, the polysilicon layer is subjected to patterning by the photolithography and etching techniques. In this manner, as shown in FIGS. 14A and 14B, the control gate 111 is formed.

Next, the N-type impurity such as phosphorus or arsenic is ion-implanted into the front surface of the Si substrate 109 below the opposite sides of the control gate 111. The Si substrate 109 is then subjected to the thermal treatment, that is, the second anneal, in order to activate the aforementioned N-type impurity. In this manner, as shown in FIGS. 2B and 2C, the source layer 115 of low breakdown voltage and the drain layer 116 of low breakdown voltage are formed on the Si substrate 109 below the opposite sides of the control gate 111. Thereafter, an interlayer insulating film, not shown, is formed over an entire part above the Si substrate 101. The interlayer insulating film and the insulating film 170 are partially removed by the photolithography and etching techniques. In this manner, contact holes C1, C2 are formed in front surfaces of the source layer 113 of high breakdown voltage and the drain layer 114 of high breakdown voltage, respectively. At the same time, contact holes C3, C4 are formed in front surfaces of the source layer 115 of low breakdown voltage and the drain layer 116 of low breakdown voltage, respectively. Furthermore, a contact hole C5 is formed in a front surface of the control gate 111. Thus, the nonvolatile memory 200 shown in FIGS. 2A to 2C is completed.

As described above, according to the second embodiment of the invention, the floating gate 105 is not placed between the channel region of the transistor Tr2 of low breakdown voltage and the control gate 111 but placed at the side under the channel region of the transistor Tr2 of low breakdown voltage, so that a distance between the channel region and the control gate 111 can be reduced. Therefore, the threshold value at the time of data readout operation can be reduced to thereby speed up the readout operation as well as to reduce the driving voltage.

In the present invention, not only the nonvolatile memory 200 but also an SOI transistor or a bulk transistor may be mounted in combination on the Si substrate 101. Such a structure achieves reduction in a voltage necessary for the nonvolatile memory that tends to require the largest drive voltage in the LSI, to thereby speed up the readout operation as well as to realize the high speed LSI with low power consumption.

Furthermore, the method for manufacturing the nonvolatile memory 200 by the SBSI method can be employed for the formation of the SOI transistor and the bulk transistor to be mounted in combination on the Si substrate 101. For example, the SOI transistor can be formed simultaneously with the transistor Tr2 of low breakdown voltage through the same process. The bulk transistor can be formed by selectively employing each of formation processes of the transistor Tr1 of high breakdown voltage and the transistor Tr2 of low breakdown voltage.

For example, a source layer and a drain layer of the bulk transistor can be formed simultaneously with the source layer 113 and the drain layer 114. A gate oxide film of the bulk transistor can be formed simultaneously with the gate oxide film 108. A gate electrode of the bulk transistor can be formed simultaneously with the control gate 111.

Therefore, the LSI, in which the SOI transistor and the bulk transistor are mounted in combination with the nonvolatile memory 200 on the same Si substrate 101, can be manufactured while suppressing the rise in the number of processes.

In the second embodiment, the Si substrate 101 corresponds to “the semiconductor substrate” of the invention. The SiGe layer 151 corresponds to “a first semiconductor layer” of the invention and the Si layer 105 corresponds to “a second semiconductor layer” of the invention. The SiGe layer 153 corresponds to “a third semiconductor layer” and the Si layer 109 corresponds to “a fourth semiconductor layer” of the invention. The supporting holes h correspond to “a second groove” of the invention and the grooves H correspond to “a first groove” of the invention. The SiO₂ film 165 corresponds to “the first insulating film” of the invention, the SiO₂ film 166 corresponds to “the second insulating film” of the invention, and the gate oxide film 108 corresponds to “the gate insulating film” of the invention. The source layer 113 and the drain layer 114 correspond to “the first source and the first drain”, respectively, and the source layer 115 and the drain layer 116 correspond to “the second source and the second drain”, respectively. The nonvolatile memory 200 corresponds to “the nonvolatile semiconductor memory device” of the invention.

What is claimed is:

1. A nonvolatile semiconductor memory device, comprising:
a first insulating film formed on a semiconductor substrate;
a floating gate formed on the first insulating film;
a second insulating film on the floating gate;
a semiconductor layer formed on the second insulating film;
a gate insulating film formed on the semiconductor layer; and
a control gate formed on the gate insulating film, wherein:
the semiconductor substrate is provided with a first source and a first drain both for writing of data; and
the semiconductor layer below both sides of the control gate is provided with a second source and a second drain both for readout of the data.

2. A method for manufacturing a nonvolatile semiconductor memory device, comprising:
forming a first semiconductor layer on a semiconductor substrate;
forming a second semiconductor layer to be served as a floating gate on the first semiconductor layer;
forming a third semiconductor layer on the second semiconductor layer;
forming a fourth semiconductor layer on the third semiconductor layer;
forming a first groove to expose a side surface of each of the fourth, the third, the second, and the first semiconductor layers by partially etching these semiconductor layers in sequence;
forming a first hollow portion between the semiconductor substrate and the second semiconductor layer and a second hollow portion between the second semiconductor layer and the fourth semiconductor layer by etching the first and the third semiconductor layers with the first groove intervened, under an etching condition that the first and the third semiconductor layers are more easily etched than the second and the fourth semiconductor layers;
forming a first insulating film inside the first hollow portion and a second insulating film inside the second hollow portion;
forming a gate insulating film on the fourth semiconductor layer;
forming a control gate on the gate insulating film;
forming a first source and a first drain both for wiring of data on the semiconductor substrate; and
forming a second source and a second drain both for readout of the data on the fourth semiconductor layer below opposite sides of the control gate.

3. The method for manufacturing a nonvolatile semiconductor memory device according to claim 2, further comprising:
forming a second groove penetrating each of the fourth, the third, the second, and the first semiconductor layers by partially etching these semiconductor layers in sequence before formation of the first and the second hollow portions; and
forming a supporter for supporting the second and the fourth semiconductor layers at least inside the second groove before the formation of the first and the second hollow portions.

4. A semiconductor device, comprising:
the nonvolatile semiconductor memory device according to claim 1;
an SOI transistor formed with the nonvolatile semiconductor memory device on the same semiconductor substrate; and
a bulk transistor formed directly to the semiconductor substrate.
